(19) United States
(12) Patent Application Publication
(10) Pub. No.: US 2013/0025786 A1
(43) Pub. Date: Jan. 31, 2013

(54) SYSTEMS FOR AND METHODS OF CONTROLLING TIME-MULTIPLEXED DEEP REACTIVE-ION ETCHING PROCESSES

(71) Applicants: Vladislav Davidkovich, Stoneham, MA (US); Martin Ryan, Reading, MA (US); David Chamberlain, Hooksett, NH (US); Philip W. Sullivan, Lexington, MA (US); Paul D. Lucas, Melrose, MA (US); John Thomas Hillhouse, Newburyport, MA (US); Robert Krmpotich, Salem, NH (US)

(72) Inventors: Vladislav Davidkovich, Stoneham, MA (US); Martin Ryan, Reading, MA (US); David Chamberlain, Hooksett, NH (US); Philip W. Sullivan, Lexington, MA (US); Paul D. Lucas, Melrose, MA (US); John Thomas Hillhouse, Newburyport, MA (US); Robert Krmpotich, Salem, NH (US)

(21) Appl. No.: 13/193,393

(22) Filed: Jul. 28, 2011

(51) Int. Cl. H01L 21/00; F15D 1/00; C23F 1/08

(52) U.S. Cl. 156/345.26; 137/596; 137/1

(57) ABSTRACT

An improved gas delivery system and method delivers a sequence of pulses of prescribed amounts of at least two gases to a process chamber of a process tool in accordance with a predetermined recipe of steps of a gas delivery process. The system comprises: a plurality of channels, each including a control valve connected so as to control each pulse of gas flowing through the corresponding channel into the process chamber of the process tool; and an exhaust valve for controlling the pressure within the process chamber, the exhaust valve including a valve controller for controlling the operation of the gas delivery system including the control valves and the exhaust valve in accordance with the predetermined recipe of steps. In one embodiment, the exhaust valve controller is configured to operate in a hybrid feedback mode including both open feedback loop control wherein the exhaust valve is set at a preselected position based on a past learned position for each step of the gas delivery process, and closed feedback loop control of the system for each step of the gas delivery process as a function of the pressure within the process chamber following the open loop control.

### CROSS-REFERENCE TO RELATED APPLICATION

Reference is made to U.S. patent application Ser. No. 12/893,554, entitled SYSTEM FOR AND METHOD OF FAST PULSE GAS DELIVERY, filed Sep. 29, 2010 in the name of Junhua Ding, and assigned to the present assignee (Attorney's Docket No. 86400-015 (MKS-218)); and U.S. patent application Ser. No. 13/035,534, entitled METHOD AND APPARATUS FOR MULTIPLE-CHANNEL PULSE GAS DELIVERY SYSTEM, filed Feb. 25, 2011 in the name of Junhua Ding and assigned to the present assignee (Attorney's Docket No. 86400-0027 (MKS-219)), both applications being incorporated herein in their entirety. The latter application is hereafter referred to as the '534 application”.

### BACKGROUND

1. Field

This disclosure relates generally to mole or gas delivery devices, and more particularly to a method of and system for pulse gas delivery (PGD). As used herein the term “gas(es)” includes the term “vapor(s)” should the two terms be considered different.

2. Overview

The manufacture or fabrication of semiconductor devices often requires the careful synchronization and precisely measured delivery of as many as a dozen gases to a process tool such as a vacuum process chamber. For purposes herein, the term “process tool” may or may not include a process chamber. Various recipes are used in the manufacturing process, involving many discrete process steps, where a semiconductor device is typically cleaned, polished, oxidized, masked, etched, doped, metalized, etc. The steps used, their particular sequence, and the materials involved all contribute to the making of particular devices.

As more device sizes have shrunk below 90 nm, one technique known as atomic layer deposition, or ALD, continues to be required for a variety of applications, such as the deposition of barriers for copper interconnects, the creation of tungsten nucleation layers, and the production of highly conducting dielectrics. In the ALD process, two or more precursor gases are delivered in pulses and flow over a wafer surface in a process tool maintained under vacuum. The two or more precursor gases flow in an alternating or sequential manner so that the gases can react with the sites or functional groups on the wafer surface. When all of the available sites are saturated from one of the precursor gases (e.g., gas A), the reaction stops and a purge gas is used to purge the excess precursor molecules from the process tool. The process is repeated, as the next precursor gas (e.g., gas B) flows over the wafer surface. For a process involving two precursor gases, a cycle can be defined as one pulse of precursor A, purge, one pulse of precursor B, and purge. A cycle can include the pulses of additional precursor gases, as well as repeats of a precursor gas, with the use of a purge gas between successive pulses of two precursor gases. This sequence is repeated until the final geometrical characteristic is reached. These sequential, self-limiting surface reactions result in one monolayer of deposited film per cycle.

The delivery of pulses of precursor gases introduced into the process tool can be controlled using on/off-type valves which are simply opened for a predetermined period of time to deliver a desired amount (mass) of precursor gas with each pulse into the process chamber of the process tool. Alternatively, a mass flow controller, which is a self-contained device comprising a transducer, control valve, and control and signal-processing electronics, is used to deliver an amount of gas (mass) at predetermined and repeatable flow rates, in short time intervals. In both cases, the amount of material (mass) flowing into the process tool is not actually measured, but inferred from measuring parameters of the ideal gas law.

Systems known as pulse gas delivery (PGD) devices have been developed that can deliver measured pulsed mass flow of precursor gases into semiconductor process tools. Such devices are designed to provide repeatable and precise quantities (mass) of gases for use in semiconductor manufacturing processes, such as atomic layer deposition (ALD) processes.

Single channel PGD devices each include a delivery reservoir or chamber containing the gas to be delivered during the ALD process upstream to the process tool. Gas is introduced into the delivery chamber through an inlet valve during a charging phase (when the corresponding inlet and outlet valves are respectively opened and closed), while gas is delivered from the delivery chamber through an outlet valve during a delivery phase. A pressure sensor and a temperature sensor are used to measure the pressure and temperature of the gas in the delivery chamber, and a dedicated controller is used to sense the pressure and temperature information and control the opening and closing of the inlet and output valves. Since the volume of the delivery is fixed and known, the amount of gas, measured moles, delivered with each pulse is a function of the gas type, the temperature of the gas in the chamber, and the pressure drop of the gas during the duration of the pulse.

Multiple channel PGD devices include multiple delivery chambers, each containing a precursor or purge gas used in a gas delivery process. Each precursor and purge gas used in a process can then be introduced through a different channel. This allows the device to operate in the charging phase for one gas provided in one channel, while delivering pulses of a gas provided in another channel. The flow of the pulse of gas from each delivery chamber is controlled with a corresponding on/off-type outlet valve between the delivery chamber of the PGD and the process tool receiving the gas. The amount of time the valve is required to be open to deliver a pulse of gas of a given mass is a further function of the starting pressures of the gas in the corresponding delivery chamber and the downstream pressure of the process tool. For example, for a given amount of gas that needs to be delivered, the starting pressure in the delivery chamber at a higher starting pressure requires a shorter time for the valve to be open than at a lower starting pressure since the mass flow occurs more quickly at the higher starting pressure. The charge period and the delivery period of PGDs are tightly controlled for fast pulse gas delivery applications in order to insure accurate delivery of prescribed amounts of gas(es). As a result, the upstream pressure of the PGDs as well as the charged pressure in the PGDs are tightly controlled in order to meet the repeatability and the accuracy requirement of the ALD process. By using multiple channels, and staggering the charging and delivery phases of the channels, the sequential delivery of pulses of different gases can be faster than achieved by a single channel device since it is possible to charge a delivery chamber of one channel, while delivering a predetermined amount of gas from the delivery chamber of another channel.

Current multichannel PGD devices include a separate dedicated channel controller for operating each channel. Each channel controller receives all of its commands from the tool/host controller used to control the process in the process tool. In this way each channel is controlled by the tool/host controller so that the entire process can be coordinated and controlled by that central controller. Thus, during a process run, the tool/host controller continually sends instruction commands to each channel controller to insure the timely and coordinated delivery of the individual pulses of gas from the multiple channels.

More recently, certain processes have been developed that require high speed pulsed or time-multiplexed processing, such processes being referred to generally as “deep reactive-ion etching”, or “DRIE” processes. For example, the semiconductor industry is developing advanced, 3-D integrated circuits thru-silicon vias (TSVs) to provide interconnect capability for die-to-die and wafer-to-wafer stacking Manufacturers are currently considering a wide variety of 3-D integration schemes that present an equally broad range of TSV etch requirements. Plasma etch technology such as the Bosch process, which has been used extensively for deep silicon etching in memory devices and MEMS production, is well suited for TSV creation. The Bosch process, also known as a high speed pulsed or time-multiplexed etching, alternates repeatedly between two modes to achieve nearly vertical structures using SF₆ and the deposition of a chemically inert passivation layer using C₄F₈. Targets for TSV required for commercial success are: adequate functionality, low cost and proven reliability.

The high speed processes require fast response times between successive pulses in order to better control the processes. While multichannel PGD devices have made the processes possible, in general the faster the device can transition between the alternating etch and passivation steps, the better the control of the process. Timing is very important for controlling the etching and passivation steps, particularly the time it takes to introduce the passivation gas following an etching step so that the etching step is stopped at a precise time. The faster the steps can be performed the better.

Accordingly, it is desirable to design a multichannel PGD device that can carry out high speed processes faster, without sacrificing the advantages of a multichannel PGD device.

Current multichannel PGD devices include a separate dedicated channel controller for operating each channel. Each channel controller receives all of its commands from the tool/host controller used to control the process in the tool. In this way each channel is controlled by the tool/host controller so that the entire process can be coordinated and controlled by that central controller. Thus, during a process run, the tool/host controller continually sends instruction commands to each channel controller to insure the timely and coordinated delivery of the individual pulses of gas from the multiple channels.

One improvement is described in the copending '534 application, wherein a multi-channel PGD system is described as comprising a dedicated multichannel controller configured so as to receive all of the instructions from the host controller or a user interface prior to running all of the process steps to be carried out by the PGD system. The multichannel controller is thus configured to control all of the individual channels through the steps of an etch-passivation process where a gas is introduced into a process tool to perform an etching process followed by the introduction of a second passivation gas to stop the etching process. The dedicated multichannel controller thus can be easily programmed to provide control signals for the multiple channels for the entire process, reducing the computing overhead of the host controller so that it is free to carry out other functions relating to the process tool. In one embodiment, the host computer or user interface provides a start command to the dedicated multichannel controller, and the controller singularly runs the process by providing all of the commands to the individual components of all of the channels while receiving the signals from the pressure and temperature sensors of the channels. While this system allows for an improved system architecture for controlling the flow of pulses into the chamber, the system does nothing to control the pressure within and the flow of fluid from the processing tool.

### DESCRIPTION OF RELATED ART

Examples of pulse mass flow delivery systems can be found in U.S. Pat. Nos. 7,615,120; 7,615,120; 7,628,860; 7,628,861, 7,662,233; 7735452 and 7794544; U.S. Patent Publication Nos. 2006/0060139; and 2006/0130755, and pending U.S. application Ser. Nos. 12/689,961, entitled CONTROL FOR AND METHOD OF PULSED GAS DELIVERY, filed Jan. 19, 2010 in the name of Paul Meneghini and assigned the present assignee (Attorney's Docket No. 56231-751 (MKS-194)); and U.S. patent application Ser. No. 12/893,554, entitled SYSTEM FOR AND METHOD OF FAST PULSE GAS DELIVERY, filed Sep. 29, 2010 in the name of Junhua Ding, and assigned to the present assignee (Attorney's Docket No. 86400-015 (MKS-218)); and U.S. patent application Ser. No. 13/035,534, entitled METHOD AND APPARATUS FOR MULTIPLE-CHANNEL PULSE GAS DELIVERY SYSTEM, filed Feb. 25, 2011 in the name of Junhua Ding and assigned to the present assignee (Attorney's Docket No. 86400-0027 (MKS-219)).

### SUMMARY

In accordance with one aspect of the improved gas delivery system for delivering a sequence of pulses of prescribed amounts of at least two gases to a process tool in accordance with a predetermined recipe of steps of a gas delivery process, comprising:
a plurality of channels, each including a control valve connected so as to control each pulse of gas flowing through the corresponding channel into the process tool; and
an exhaust valve for controlling the pressure within the process tool, the exhaust valve including a valve controller configured to control the operation of the gas delivery system including control valves and the exhaust valve, in accordance with the predetermined recipe of steps.

In accordance with another aspect of the invention, the combination of a process tool system including a process chamber, and a pulse gas delivery system for delivering a sequence of pulses of prescribed amounts of gases to a process tool is provided, wherein the pulse gas delivery system comprises:
a plurality of channels, each including a control valve connected so as to control each pulse of gas flowing through the corresponding channel into the process chamber; and
an exhaust valve for controlling the pressure within the process chamber, the exhaust valve including a valve controller configured to control the operation of the process tool system including the control valves and the exhaust valve in accordance with the predetermined recipe of steps.

A method of delivering a sequence of pulses of prescribed amounts of gases in accordance with the steps of a recipe to a process chamber of a process tool using a pulse gas delivery system comprising a plurality of channels, each channel including a control valve connected so as to control the duration of each pulse of gas flowing through the corresponding channel into the process chamber of the process tool; and an exhaust valve for controlling the pressure within the process chamber, the exhaust valve including a valve controller for controlling the operation of the control valves and the exhaust valve in accordance with the predetermined recipe of steps; the method comprising:
configuring the valve controller so that the controller controls (a) the pressure within the chamber by controlling the position of the valve body of the exhaust valve, and (b) the opening and closing of the control valves of each of the channels so that pulses of gases can be provided to the process tool in a predetermined sequence in accordance with the recipe of steps.

In accordance with another aspect of the invention, the exhaust valve controller is configured to operate in a hybrid feedback mode including both open feedback loop control wherein the exhaust valve is set at a preselected position based on a past learned position for each step of the gas delivery process, and closed feedback loop control of the system for each step of the gas delivery process as a function of the pressure within the process tool following the open loop control.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings disclose illustrative embodiments. They do not set forth all embodiments. Other embodiments may be used in addition or instead. Details which may be apparent or unnecessary may be omitted to save space or for more effective illustration. Conversely, some embodiments may be practiced without all of the details which are disclosed. When the same numeral appears in different drawings, it refers to the same or like components or steps.

In the drawings:

FIG. 1 is a block diagram of one embodiment of a multichannel gas delivery system utilizing an exhaust valve controller configured to provide high speed pulse delivery;

FIG. 2 is a timing diagram further illustrating hybrid control;

FIG. 3 is simplified block diagram illustrating open loop control of the hybrid control approach;

FIG. 4 shows a simplified block diagram illustrating closed loop control of the hybrid control approach; and

FIG. 5 shows a flow chart of one embodiment of steps of a typical pulse gas delivery process including hybrid control.

### DETAILED DESCRIPTION OF ILLUSTRATIVE EMBODIMENTS

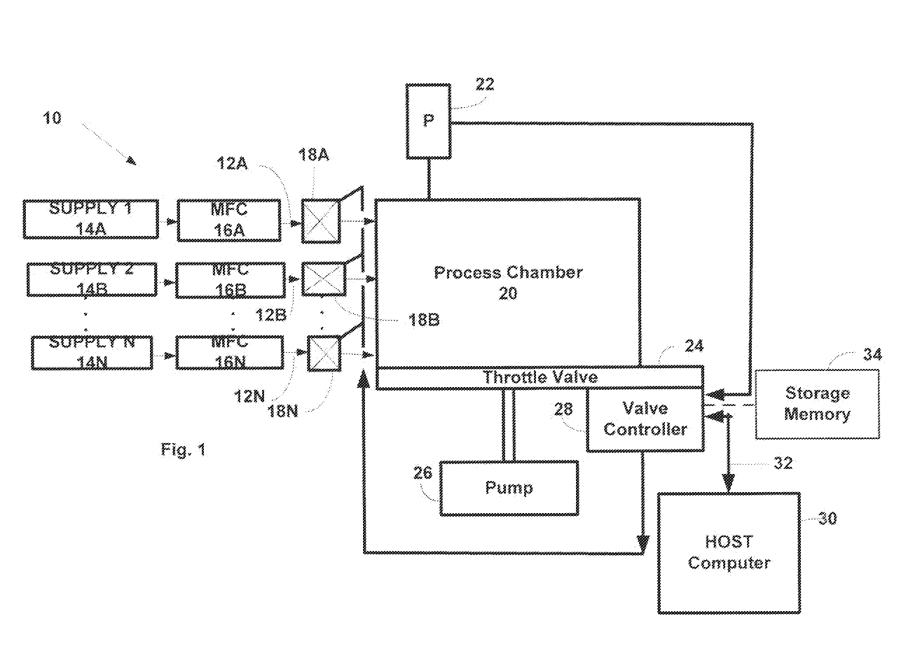

FIG. 1 illustrates a block diagram of one embodiment of a multichannel PGD system, indicated generally at 10, in which the exhaust valve controller is configured to provide control of high speed pulse delivery of a gas in accordance with the predetermined recipe of steps of a pulse gas delivery process. The system 10 and method are particularly intended to deliver contaminant-free, precisely metered quantities of process gases to a process tool, such as a semiconductor process chamber, or a plasma etching machine, in a very fast and accurate sequence.

Referring to FIG. 1, the illustrated exemplary multiple gas delivery system 10 includes multiple channels 12. Each channel 12 is a gas supply line connected to a gas supply 14 and configured to provide a specific gas to process tool, illustrated as including the process chamber 20. More specifically, system 10 includes individual gas supplies 14, which can be in the form of multiple delivery chambers, each containing a precursor or purge gas used in a gas delivery process. Each precursor and purge gas used in a process can then be introduced through a different channel 12. This allows the device to operate in the charging phase for one gas provided in one channel, while delivering pulses of a gas provided in another channel. The flow of the pulse of gas from each delivery chamber is controlled with a corresponding on/off-type outlet valve 18 between the process tool shown as including a process chamber 20. The amount of time the valve is required to be open to deliver a pulse of gas of a given mass is a further function of the starting pressures of the gas in the corresponding delivery chamber and the downstream pressure of the process tool. For example, for a given amount of gas that needs to be delivered, the starting pressure in the delivery chamber at a higher starting pressure requires a shorter time for the valve to be open than at a lower starting pressure since the mass flow occurs more quickly at the higher starting pressure. The charge period and the delivery period of PGDs are tightly controlled for fast pulse gas delivery applications in order to insure accurate delivery of prescribed amounts of gas(es). As a result, the upstream pressure of the PGDs as well as the charged pressure in the PGDs are tightly controlled in order to meet the repeatability and the accuracy requirement of the ALD process. By using multiple channels, and staggering the charging and delivery phases of the channels, the sequential delivery of pulses of different gases can be faster than achieved by a single channel device since it is possible to charge a delivery chamber of one channel, while delivering a predetermined amount of gas from the delivery chamber of another channel.

Thus, each channel includes a pulse control valve 18 for controlling the duration of each pulse of gas delivered through that channel 12 to the process chamber 20. Each channel may also include a mass flow controller 16 configured to control the amount of gas of each pulse delivered through the corresponding pulse control valve 18, although the mass flow controllers are not essential to accomplish the advantages described herein. In the illustrated embodiment, the pulse control valves 18 can be shut-off valves having relatively fast shut off responses, i.e., transition between a fully open state and a fully shut off state quickly. For example, the shut off valves can transition between the two states on the order of between one and five milliseconds, although this can clearly vary based upon a number of factors, such as the valves used, the process controlled by the system 10, etc. A pressure sensor 22 is provided for the process chamber so that the pressure within the chamber 20 can be monitored as a part of the control of the pulse gas delivery process described herein, since the required time duration of each pulse is at least a partial function of the pressure within the process chamber 20. As will be more apparent hereinafter, the pressure within the process chamber is controlled by using a vacuum pump 26 to pump gas from the process chamber 20, and controlling the rate at which the gas is pumped from the chamber by controlling the position of the valve body of exhaust valve 24. Exhaust valve is in the form of a throttle valve, and in one embodiment is in the form of a pendulum valve. The throttle valve 24 should have a very fast response time, e.g. the transition time between a fully closed position and a fully opened position is in the order of 600 millisec. The throttle valve 24 includes an exhaust valve controller 28, provided to control the operation of the throttle valve, but is modified to control the opening and closing of the pulse control valves 18 and the throttle valve 24 so as to control all of the steps of the pulse delivery process. The exhaust valve controller 28 can receive from the host computer 30, or some other device through a user interface 32, the specific recipe instructions for processing the recipe of steps of the gas delivery process carried out in the chamber 20. Similarly, the process can be initiated with a command through user interface 32 from host computer 30 or other device. Storage memory 34 is provided for storing instructions and data relating to the detailed steps of the recipe, as well as learned data relating to the approximate position of the valve body of the throttle valve for each step, the need for which will become more evident hereinafter. Memory 34 can be internal or external of the valve controller 28, but should be dedicated for use in operating valve 24 to control the pressure within the process chamber 20 with each step of the stored recipe of steps. Using the memory 34 to store the sequence of each recipe allows for valve controller 28 to control the pressure within and flow from the process chamber 20 separate from the host computer 30 in accordance with the each step of each stored recipe.

The exhaust valve controller 28 is connected to receive pressure signals from the pressure sensor 22, as well as control the valves 18 and 24 all in accordance with the instruction steps provided in memory 34 so as to carry out the stored recipe. The exhaust valve controller 28 thus controls (a) the duration of each gas pulse by the opening and closing of the appropriate valves 18 in the proper sequence determined by the recipe as a function of the pressure readings provided from sensor 22, and (b) the pressure of the gas in the chamber by controlling the position of the valve body of the throttle valve. With the recipe steps stored in memory 34, the exhaust valve controller can run an entire process with a single start command from the host computer 30, or other device, provided through user interface 32, without further need for the user or the host computer to interact with the system, unless it is desired to prematurely end the process. In the later case a single stop command can be initiated and provided to the exhaust valve controller. This approach provides better feedback, and also reduces the amount of computer overhead for the host computer, and less interaction by the user through the user interface.

Many recipes can require the system to continuously run for a relatively long time, e.g., 60 minutes, and execute a large number of commands, e.g., 1000 steps, within that time frame. Because of the long run time, and the various electro-mechanical operations of the system during the run time, variations in system performance can occur as a process proceeds through all of the steps of a recipe. Such variations can occur due to various factors, including variations in the response time of the pulse control valves, variations in pressure control within the process chamber due to heat build up in the various moving parts as the process proceeds, etc. As a consequence, it has been found that providing only closed loop system control can impose limits on how fast each step of the recipe can be performed since a typical recipe requires the system to be reconfigured at the beginning of each step, requiring a certain amount of settling time.

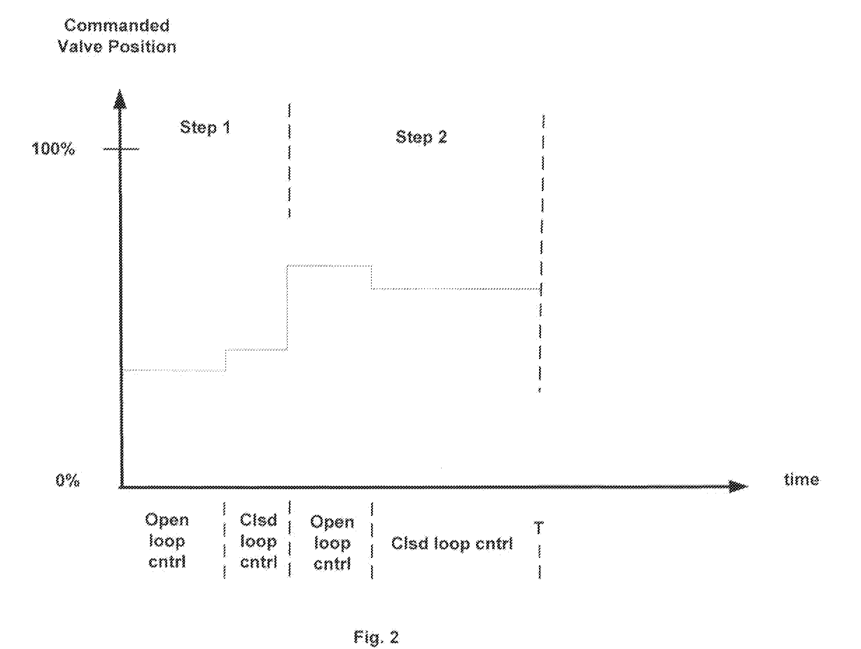

Accordingly, another aspect of the invention is to control the gas delivery process using a hybrid open and closed loop control approach, including partially open loop control and partially closed loop control. Open loop control uses data that is previously generated by running the steps in the prescribed sequence of each recipe in its entirety as closed loop controlled system during a “training run”, and generating data representing the valve body position for each step. This data can be stored in memory 34. The hybrid open and closed loop approach to controlling the valve position of valve 24 during a recipe process is illustrated in FIG. 2, where two steps of a typical recipe are shown by way of example. At the beginning of each such step of the recipe, the system operates in an initial open loop control phase in which the valve position setting of the valve body of valve 28 for a particular step of the recipe is set based on data stored in the memory corresponding to the step of the recipe and determined during a prior training run. Once in position the process step continues for a predetermined amount of time (as a part of the entire step) partly as a function of the pressure within the process chamber 20, before allowing the system to change to a closed loop control phase converging on the desired pressure to complete the step. The closed loop control phase enables the system to converge on the correct value in a much faster response time than would otherwise be achieved with a totally closed loop system control scheme because the hybrid approach moves the valve body during the first phase of the step closer to the end position of the step prior to starting the second closed loop control phase. In this way there is less chance of under- or over shoot during closed loop control operation.

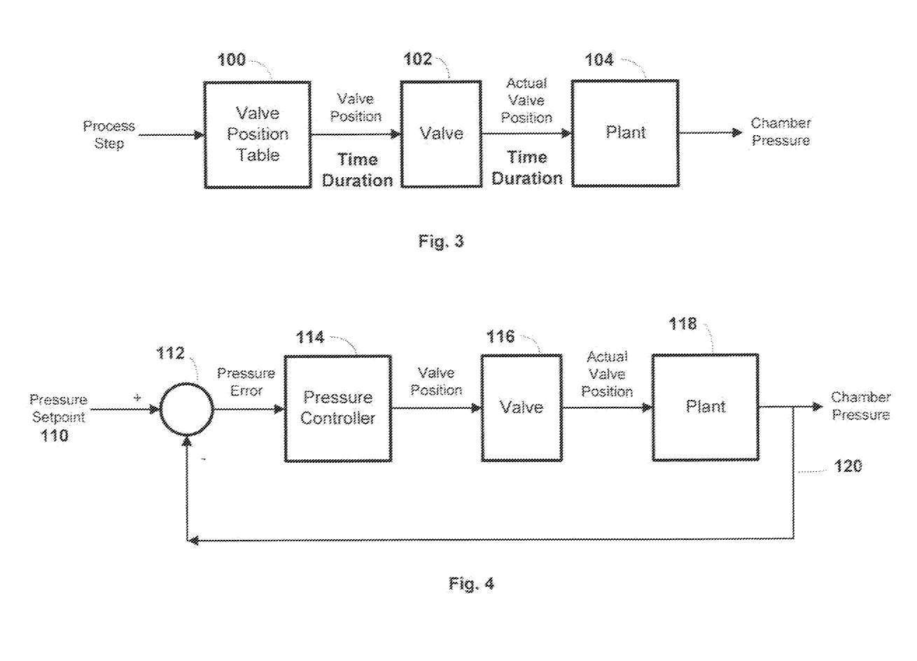

As shown in more detail in FIG. 3, the open loop control for each step includes looking up the valve position and time duration information from a look up table 100 of storage memory 34, and providing a signal representing the valve position and corresponding duration to the valve at 102. This provides the actual valve position for the corresponding time duration during the first phase of each process step controlled by the hybrid method at 104 so as to achieve the chamber pressure as a result of the first phase of the each step.

The closed loop control phase of each process step shown in FIG. 4 includes an input signal representing the pressure set point being applied at input 110 to the summing junction 112. Summing junction 112 receives a feed back signal representing the actual pressure in the chamber so as to provide an error signal representing the difference between the two at its output (pressure error). The signal representing the pressure error is provided at the input of the pressure controller 114, which sets the valve position of the valve 116 at the corresponding value to correct for any error. The actual valve position is provided to the plant 118, which in turn provides a signal representing the actual chamber pressure of plant 118. The output of plant 118 provides the feedback signal through feedback loop 120 to the summing junction 112. As described, each step requiring hybrid control uses both open loop and closed loop control.

As mentioned, for each recipe the system requires data to be stored in the storage memory preferably in the form of a table for the open loop control. The data can be generated by running the system with closed loop control during a training run of the recipe. Once the data is acquired, the system can operate with hybrid control.

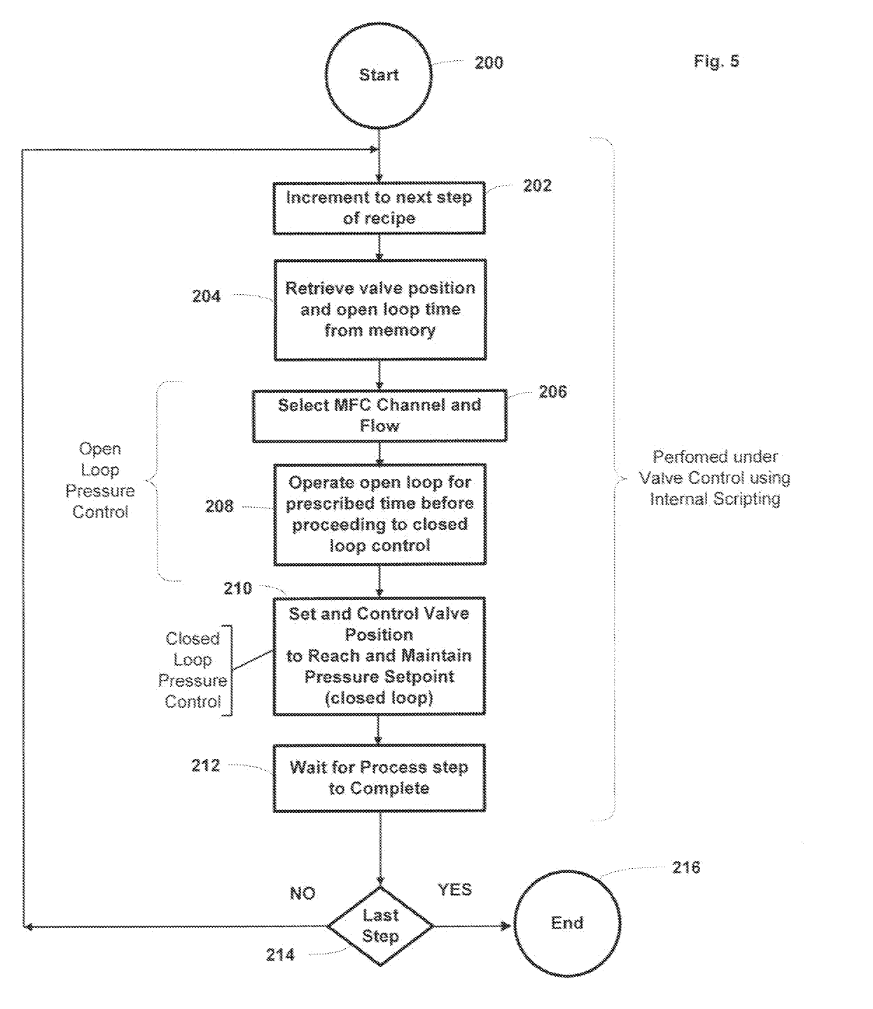

FIG. 5 shows a flow chart illustrating each step under hybrid control during a pulse gas delivery process. As shown, with data stored in memory 34, the hybrid control process begins at 200. The process increments through each step of the recipe requiring hybrid control, starting with the first step at 202. The data relating valve position and time duration that the valve is required to be open during the first phase of the step is retrieved from memory 34 as shown at 204. At step 206, the channel used to deliver gas for the next step of the recipe is selected and enabled by opening the corresponding valve 18 (and if used MFC 16). At this time the system is enabled to operate in the first phase of the process step of the recipe and can now proceed as indicated at 208, wherein the system operates with open loop control for the prescribed time. Once the prescribed time ends the system can then proceed to the second phase of loop control at 210, wherein the exhaust valve body is moved if necessary, and the system is allowed to proceed with closed loop control for the second phase of the step. The pressure within the chamber will usually settle on the set point more quickly than would be achieved with just closed loop control, because in many steps the closed loop control starts at a position closer following the positioning of the controlling element in the beginning of the first phase of the process step. The system waits for the process step to complete at 212, and proceeds to step 214. A determination is made whether the last step of hybrid control of the process has been completed. If not the process repeats steps 202-212, before making the determination again. If the system has completed the last step of hybrid control of the process, then hybrid control ends at step 216.

In operation, the process steps for the multichannel PGD device 10 are provided to the exhaust valve controller 28 by uploading a program to the controller 28 through the user interface 32 from host controller 30 or other device. The system is operating in a training run so that data can be stored in memory. Once the controller is properly programmed, the system is now ready to operate under hybrid control.

The exhaust valve controller 28 is configured to provide data and instructions to and from the components making up each of the channels, as well as any additional data and instructions to and from a user interface/host computer 28. The user interface/host computer 30 can be any suitable device such as a computer including a keyboard and monitor configured so that an operator can operate the PGD system 10. It should be apparent, that wherein the host computer is the computer used to operate the tool, the use of the dedicated controller to run the sequence of steps frees up operating overhead of the host computer, allowing it to operate more efficiently.

It should be evident that various changes can be made to the embodiments described without departing from the scope of the claims. For example, while the embodiment described utilizes the valve controller to control the pressure within the chamber of the tool, and the position of the throttle valve, the valve controller can also be used to control the mass flow controllers 16A-16N, and control valves 18A-18N. With such an arrangement the valve controller need only issue a start and stop commands for the entire recipe run, which is controlled by the valve controller.

The components, steps, features, objects, benefits and advantages which have been discussed are merely illustrative. None of them, nor the discussions relating to them, are intended to limit the scope of protection in any way. Numerous other embodiments are also contemplated. These include embodiments which have fewer, additional, and/or different components, steps, features, objects, benefits and advantages. These also include embodiments in which the components and/or steps are arranged and/or ordered differently.

Unless otherwise stated, all measurements, values, ratings, positions, magnitudes, sizes, and other specifications which are set forth in this specification, including in the claims which follow, are approximate, not exact. They are intended to have a reasonable range which is consistent with the functions to which they relate and with what is customary in the art to which they pertain.

All articles, patents, patent applications, and other publications which have been cited in this disclosure are hereby incorporated herein by reference.

The phrase “means for” when used in a claim is intended to and should be interpreted to embrace the corresponding structures and materials which have been described and their equivalents. Similarly, the phrase “step for” when used in a claim is intended to and should be interpreted to embrace the corresponding acts which have been described and their equivalents. The absence of these phrases in a claim means that the claim is not intended to and should not be interpreted to be limited to any of the corresponding structures, materials, or acts or to their equivalents.

Nothing which has been stated or illustrated is intended or should be interpreted to cause a dedication of any component, step, feature, object, benefit, advantage, or equivalent to the public, regardless of whether it is recited in the claims.

The scope of protection is limited solely by the claims which now follow. That scope is intended and should be interpreted to be as broad as is consistent with the ordinary meaning of the language which is used in the claims when interpreted in light of this specification and the prosecution history which follows and to encompass all structural and functional equivalents.

What is claimed is:

1. A gas delivery system for delivering a sequence of pulses of prescribed amounts of at least two gases to a process tool in accordance with a predetermined recipe of steps of a gas delivery process, comprising:
a plurality of channels, each including a control valve connected so as to control each pulse of gas flowing through the corresponding channel into the process tool; and
an exhaust valve for controlling the pressure within the process tool, the exhaust valve including a valve controller configured to control the operation of the gas delivery system including control valves and the exhaust valve, in accordance with the predetermined recipe of steps.

2. A system according to claim 1, wherein the gas delivery system includes a plurality of mass flow controllers and pulse control valves, and the valve controller is also configured to control the operation of the mass flow controllers and pulse control valves.

3. A system according to claim 1, wherein the tool is of the type including a host computer, wherein the pulse gas delivery process is initiated by an instruction provided by the host computer to the exhaust valve controller.

4. A system according to claim 1, further including a user interface coupled to the dedicated multiple channel controller so that the pulse gas delivery process is initiated by an instruction provided through the user interface to the exhaust valve controller.

5. A system according to claim 1, wherein the exhaust valve controller is configured to operate in a hybrid feedback mode including both open feedback loop control and a closed feedback loop control of the system during the gas delivery process.

6. A system according to claim 1, wherein the exhaust valve controller is configured to operate in a hybrid feedback mode including both open feedback loop control and a closed feedback loop control of the system during each step of the gas delivery process.

7. A system according to claim 1, wherein the exhaust valve controller is configured to operate in a hybrid feedback mode including both open feedback loop control wherein the exhaust valve is set at a preselected position based on a past learned position for each step of the gas delivery process, and closed feedback loop control of the system for each step of the gas delivery process as a function of the pressure within the process tool following the open loop control.

8. A system according to claim 7, wherein exhaust valve is a throttle valve configured to control the pressure within the process tool, and the exhaust valve controller is configured to provide a signal to open and precisely control the open position of a throttle valve so as to control the pressure within the process tool.

9. A system according to claim 7, wherein the exhaust valve is positioned during the open loop control of each step as a function of stored data, and during the closed loop control of each step as a function of the pressure within the process tool.

10. A system according to claim 9, wherein the stored data is acquired from prior operation of the system in accordance with the recipe of steps.

11. The combination of a process tool system including a process chamber, and a pulse gas delivery system for delivering a sequence of pulses of prescribed amounts of gases to a process tool, the pulse gas delivery system comprising:
a plurality of channels, each including a control valve connected so as to control each pulse of gas flowing through the corresponding channel into the process chamber; and
an exhaust valve for controlling the pressure within the process chamber, the exhaust valve including a valve controller configured to control the operation of the process tool system including the control valves and the exhaust valve in accordance with the predetermined recipe of steps.

12. The combination of claim 11, wherein the gas delivery system includes a plurality of mass flow controllers and pulse control valves, and the valve controller is also configured to control the operation of the mass flow controllers and pulse control valves.

13. A combination according to claim 11, wherein the process tool system is of the type including a host computer, wherein the pulse gas delivery process is initiated by an instruction provided by the host computer to the exhaust valve controller.

14. A combination according to claim 11, further including a user interface coupled to the dedicated multiple channel controller so that the pulse gas delivery process is initiated by an instruction provided through the user interface to the exhaust valve controller.

15. A combination according to claim 11, wherein the exhaust valve controller is configured to operate in a hybrid feedback mode including both open feedback loop control and a closed feedback loop control of the system during the gas delivery process.

16. A combination according to claim 11, wherein the exhaust valve controller is configured to operate in a hybrid feedback mode including both open feedback loop control and a closed feedback loop control of the system during each step of the gas delivery process.

17. A combination according to claim 11, wherein the exhaust valve controller is configured to operate in a hybrid feedback mode including both open feedback loop control wherein the exhaust valve is set at a preselected position based on a past learned position for each step of the gas delivery process, and closed feedback loop control of the system for each step of the gas delivery process as a function of the pressure within the process chamber following the open loop control.

18. A combination according to claim 17, wherein exhaust valve is a throttle valve configured to control the pressure within the process chamber, and the exhaust valve controller is configured to provide a signal to open and precisely control the open position of a throttle valve so as to control the pressure within the process chamber.

19. A combination according to claim 17, wherein the exhaust valve is positioned during the open loop control of each step as a function of stored data, and during the closed loop control of each step as a function of the pressure within the process chamber.

20. A combination according to claim 19, wherein the stored data is acquired from prior operation of the system in accordance with the recipe of steps.

21. A method of delivering a sequence of pulses of prescribed amounts of gases in accordance with the steps of a recipe to a process chamber of a process tool using a pulse gas delivery system comprising a plurality of channels, each channel including a control valve connected so as to control the duration of each pulse of gas flowing through the corresponding channel into the process chamber of the process tool; and an exhaust valve for controlling the pressure within the process chamber, the exhaust valve including a valve controller for controlling the operation of the pulse gas delivery system including the control valves and the exhaust valve in accordance with the predetermined recipe of steps; the method comprising:
configuring the valve controller so that the controller controls (a) the pressure within the chamber by controlling the position of the controlling element of the exhaust valve, and (b) the opening and closing of the control valves of each of the channels so that pulses of gases can be provided to the process tool in a predetermined sequence in accordance with the recipe of steps.

22. A method according to claim 21, wherein the gas delivery system includes a plurality of mass flow controllers and pulse control valves, and wherein the step of configuring includes configuring the valve controller so that the valve controller controls the operation of the mass flow controllers and pulse control valves in accordance with the recipe of steps.

23. A method according to claim 21, further including initiating the pulse gas delivery process with an instruction provided by a host computer to the exhaust valve controller.

24. A method according to claim 23, further including initiating the pulse gas delivery process through a user interface coupled to the exhaust valve controller.

25. A method according to claim 21, further including configuring the valve controller so as to operate in a hybrid feedback mode including both open feedback loop control and a closed feedback loop control of the system during the gas delivery process.

26. A method according to claim 21, configuring the exhaust valve controller so as to operate in a hybrid feedback mode including both open feedback loop control and a closed feedback loop control of the system during each step of the gas delivery process.

27. A method according to claim 21, further including configuring the valve controller so as to operate in a hybrid feedback mode including both open feedback loop control wherein the exhaust valve is set at a preselected position based on a past learned position for each step of the gas delivery process, and closed feedback loop control of the system for each step of the gas delivery process as a function of the pressure within the process chamber following the open loop control.

28. A method according to claim 27, wherein the exhaust valve is a throttle valve, and configuring the valve controller so as to provide a signal to precisely control the open position of a throttle valve so as to control the pressure within the process chamber.

29. A method according to claim 27, further including positioning the exhaust valve during the open loop control of each step of the gas delivery process as a function of stored data, and then controlling the position of the valve as a function of a set point during the closed loop control of each step of the gas delivery process.

30. A method according to claim 29, further including acquiring the stored data from prior operation of the system operating in a closed loop control in accordance with the recipe of steps.
